(19) United States
(12) Patent Application Publication
(10) Pub. No.: US 2026/0031310 A1
(43) Pub. Date: Jan. 29, 2026

(54) COMPONENT REPLACEMENT SYSTEM

(71) Applicant: Tokyo Electron Limited, Tokyo (JP)

(72) Inventors: Dai KITAGAWA, Miyagi (JP); Koei ITO, Miyagi (JP); Hiroki ENDO, Miyagi (JP); Suguru SATO, Miyagi (JP); Taisei SEGUCHI, Miyagi (JP)

(73) Assignee: Tokyo Electron Limited, Tokyo (JP)

(21) Appl. No.: 19/348,962

(22) Filed: Oct. 3, 2025

Related U.S. Application Data
(63) Continuation of application No. PCT/JP2024/007839, filed on Mar. 1, 2024.

(30) Foreign Application Priority Data
Apr. 10, 2023 (JP) 2023-063706

(51) Int. Cl. H01J 37/32

(52) U.S. Cl. CPC H01J 37/32807; H01J 37/32568; H01J 37/32642

(57) ABSTRACT

The component replacement system includes a plasma processing apparatus and a mobile type replacement apparatus. A consumable component is disposed in a plasma processing module of the plasma processing apparatus, a container includes a housing which stores the consumable component. The mobile type replacement apparatus includes an upper surface lid to engage with bottom surface lid of the housing, a lock release mechanism to release a lock state of the upper surface lid and the bottom surface lid, a lid removal mechanism to remove the upper surface lid and the bottom surface lid together, a lifting and lowering mechanism to move the consumable component in a vertical direction between an inside of the container and an inside of the mobile type replacement apparatus, and a component replacement robot to transport the consumable component between an inside of the mobile type replacement apparatus and the plasma processing module.

### CROSS-REFERENCE TO RELATED APPLICATIONS

This application is a bypass continuation application of international application No. PCT/JP2024/007839 having an international filing date of Mar. 1, 2024 and designating the United States, the international application being based upon and claiming the benefit of priority from Japanese Patent Application No. 2023-063706, filed on Apr. 10, 2023, the entire contents of each of which are incorporated herein by reference.

### BACKGROUND

An exemplary embodiment of the present disclosure relates to a component replacement system. For example:

Japanese Patent Application Laid-Open No. 2021-176173 discloses a technique for replacing components used in a plasma processing apparatus.

### SUMMARY

A component replacement system according to an exemplary embodiment of the present disclosure includes a plasma processing apparatus, a portable type component storage container and a mobile type replacement apparatus. The plasma processing apparatus includes: a plasma processing module having a first side surface and a second side surface, wherein the first side surface includes a first opening and the second side surface includes a second opening; a consumable component disposed in the plasma processing module; and a vacuum transport module having a third side surface, wherein the vacuum transport module is connected to the plasma processing module such that a substrate is transported between the vacuum transport module and the plasma processing module via the first opening surface and a third opening. The portable type component storage container includes a housing to store the consumable component, wherein the housing includes at least one bottom surface lid attached to close a bottom surface opening of a bottom surface, and the at least one bottom surface lid is locked to the bottom surface. The mobile type replacement apparatus has a fourth side surface and an upper surface, and the mobile type replacement apparatus includes: at least one upper surface lid attached to close an upper surface opening of the upper surface, wherein the at least one upper surface lid is locked to the upper surface, and the at least one upper surface lid engages with the at least one bottom surface lid when the portable type component storage container is connected to the mobile type replacement apparatus; a lock release mechanism to release a lock state of the at least one upper surface lid and the at least one bottom surface lid when the portable type component storage container is connected to the mobile type replacement apparatus; a lid removal mechanism to remove the at least one upper surface lid and the at least one bottom surface lid together when the portable type component storage container is connected to the mobile type replacement apparatus and when the lock state of the at least one upper surface lid and the at least one bottom surface lid is released; a lifting and lowering mechanism to move the consumable component in a vertical direction between a first position in the portable type component storage container and a second position in the mobile type replacement apparatus via the bottom surface opening and the upper surface opening when the portable type component storage container is connected to the mobile type replacement apparatus and when the at least one upper surface lid and the at least one bottom surface lid are removed; and a component replacement robot to transport the consumable component between the second position in the mobile type replacement apparatus and the plasma processing module via a fourth opening of the fourth side surface and the second opening when the mobile type replacement apparatus is connected to the plasma processing module.

### BRIEF DESCRIPTION OF DRAWINGS

FIG. 1 is a diagram illustrating a configuration example of a component replacement system.

FIG. 2 is a diagram illustrating a configuration example of a capacitively coupled plasma processing module.

FIG. 3 is a diagram illustrating a configuration example of a portable type component storage unit.

FIG. 4 is a diagram illustrating an example of an internal configuration of the portable type component storage unit.

FIG. 5 is a diagram illustrating an example of the internal configuration of the portable type component storage unit.

FIG. 6 is a diagram illustrating an example of a lock mechanism of the portable type component storage unit.

FIG. 7 is a diagram illustrating an example of a configuration of a mobile type replacement apparatus.

FIG. 8 is a diagram for describing an example of a lock release mechanism of the mobile type replacement apparatus.

FIG. 9 is a diagram illustrating an example of a state where an upper surface lid and a bottom surface lid are removed.

FIG. 10 is a diagram illustrating an example of a state where a consumable component is delivered to a component replacement robot.

FIG. 11 is a diagram illustrating an example of a configuration of a mobile type replacement apparatus including two upper surface lids corresponding to two bottom surface lids.

FIG. 12 is a diagram illustrating an example of a configuration of the mobile type replacement apparatus including the two upper surface lids corresponding to the two bottom surface lids.

FIG. 13 is a diagram illustrating an example of a configuration of a jig that holds a consumable component in the portable type component storage unit.

FIG. 14 is a diagram illustrating an example of a configuration of a jig that holds a consumable component in the portable type component storage unit.

FIG. 15 is a diagram illustrating an example of a configuration of a U-shaped jig.

FIG. 16 is a diagram illustrating an example of a configuration of a mobile type replacement apparatus in a second embodiment.

FIG. 17 is a diagram illustrating a configuration example of a portable type component storage unit in the second embodiment.

FIG. 18 is a diagram illustrating a state where the upper surface lid is held by a lifting and lowering mechanism in the second embodiment.

FIG. 19 is a diagram illustrating an example of a state where the consumable component in the second embodiment is delivered to the component replacement robot.

FIG. 20 is a diagram illustrating an example of a configuration of a mobile type replacement apparatus in a third embodiment.

FIG. 21 is a diagram illustrating a configuration example of a portable type component storage unit in the third embodiment.

FIG. 22 is a diagram illustrating an example of an opening and closing mechanism of a load port in the third embodiment.

### DETAILED DESCRIPTION

Hereinafter, each embodiment according to the present disclosure will be described.

In one exemplary embodiment, a component replacement system is provided, which includes:
a plasma processing apparatus, the plasma processing apparatus including a plasma processing module having a first side surface and a second side surface, a consumable component disposed in the plasma processing module, and a vacuum transport module having a third side surface, the vacuum transport module being connected to the plasma processing module to be able to transport a substrate between the vacuum transport module and the plasma processing module via a first opening of the first side surface and a third opening of the third side surface;
a portable type component storage unit, the portable type component storage unit including a housing, the housing being able to store the consumable component, the housing including at least one bottom surface lid attached to close a bottom surface opening of a bottom surface, and the at least one bottom surface lid being locked to the bottom surface; and
a mobile type replacement apparatus having a fourth side surface and an upper surface, the mobile type replacement apparatus including at least one upper surface lid attached to close an upper surface opening of the upper surface, the at least one upper surface lid being locked to the upper surface, and the at least one upper surface lid being configured to engage with the at least one bottom surface lid when the portable type component storage unit is connected to the mobile type replacement apparatus, a lock release mechanism configured to release a lock state of the at least one upper surface lid and the at least one bottom surface lid when the portable type component storage unit is connected to the mobile type replacement apparatus, a lid removal mechanism configured to remove the at least one upper surface lid and the at least one bottom surface lid together when the portable type component storage unit is connected to the mobile type replacement apparatus and when the lock state of the at least one upper surface lid and the at least one bottom surface lid is released, a lifting and lowering mechanism configured to move the consumable component in a vertical direction between a first position in the portable type component storage unit and a second position in the mobile type replacement apparatus via the bottom surface opening and the upper surface opening when the portable type component storage unit is connected to the mobile type replacement apparatus and when the at least one upper surface lid and the at least one bottom surface lid are removed, and a component replacement robot configured to transport the consumable component between the second position in the mobile type replacement apparatus and the plasma processing module via a fourth opening of the fourth side surface and a second opening of the second side surface when the mobile type replacement apparatus is connected to the plasma processing module.

In one exemplary embodiment, the plasma processing module includes a plasma processing chamber, and a substrate support disposed in the plasma processing chamber and having a substrate support surface and a ring support surface, and the consumable component is an annular member disposed on the ring support surface to surround the substrate on the substrate support surface.

In one exemplary embodiment, the plasma processing module includes a plasma processing chamber, and a substrate support disposed in the plasma processing chamber, and the consumable component is an upper electrode plate disposed above the substrate support.

In one exemplary embodiment, the plasma processing module includes a first chamber, and the consumable component is a second chamber disposed in the first chamber.

In one exemplary embodiment, the at least one bottom surface lid includes N (N is an integer of 2 or more) bottom surface lids, the at least one upper surface lid includes N upper surface lids each corresponding to the N bottom surface lids, and each upper surface lid is configured to engage with a corresponding bottom surface lid when the portable type component storage unit is connected to the mobile type replacement apparatus.

In one exemplary embodiment, the portable type component storage unit is configured to be transported by a ceiling traveling type shuttle.

In one exemplary embodiment, a component replacement system is provided, which includes:
a plasma processing apparatus, the plasma processing apparatus including a plasma processing module having a first side surface and a second side surface, a consumable component disposed in the plasma processing module, and a vacuum transport module having a third side surface, the vacuum transport module being connected to the plasma processing module to be able to transport a substrate between the vacuum transport module and the plasma processing module via a first opening of the first side surface and a third opening of the third side surface;
a portable type component storage unit, the portable type component storage unit including a housing, the housing being able to store the consumable component, the housing including at least one bottom surface lid attached to close a bottom surface opening of a bottom surface, and the at least one bottom surface lid being locked to the bottom surface; and
a mobile type replacement apparatus having a fourth side surface and an upper surface, the mobile type replacement apparatus including at least one upper surface lid attached to close an upper surface opening of the upper surface, the at least one upper surface lid being locked to the upper surface, and the at least one upper surface lid being configured to engage with the at least one bottom surface lid when the portable type component storage unit is connected to the mobile type replacement apparatus, a lock release mechanism configured to release a lock state of the at least one upper surface lid and the at least one bottom surface lid when the portable type component storage unit is connected to the mobile type replacement apparatus, a lifting and lowering mechanism configured to move the at least one upper surface lid and the at least one bottom surface lid together in a vertical direction, and to move the consumable component supported by the at least one bottom surface lid in the vertical direction between a first position in the portable type component storage unit and a second position in the mobile type replacement apparatus via the bottom surface opening and the upper surface opening, when the portable type component storage unit is connected to the mobile type replacement apparatus and when the lock state of the at least one upper surface lid and the at least one bottom surface lid is released, and a component replacement robot configured to transport the consumable component between the second position in the mobile type replacement apparatus and the plasma processing module via a fourth opening of the fourth side surface and a second opening of the second side surface when the mobile type replacement apparatus is connected to the plasma processing module.

In one exemplary embodiment, the plasma processing module includes a plasma processing chamber, and a substrate support disposed in the plasma processing chamber and having a substrate support surface and a ring support surface, and the consumable component is an annular member disposed on the ring support surface to surround the substrate on the substrate support surface.

In one exemplary embodiment, the plasma processing module includes a plasma processing chamber, and a substrate support disposed in the plasma processing chamber, and the consumable component is an upper electrode plate disposed above the substrate support.

In one exemplary embodiment, the plasma processing module includes a first chamber, and the consumable component is a second chamber disposed in the first chamber.

In one exemplary embodiment, the at least one bottom surface lid includes N (N is an integer of 2 or more) bottom surface lids, the at least one upper surface lid includes N upper surface lids each corresponding to the N bottom surface lids, and each upper surface lid is configured to engage with a corresponding bottom surface lid when the portable type component storage unit is connected to the mobile type replacement apparatus.

In one exemplary embodiment, the portable type component storage unit is configured to be transported by a ceiling traveling type shuttle.

In one exemplary embodiment, a component replacement system is provided, which includes:
a plasma processing apparatus, the plasma processing apparatus including a plasma processing module having a first side surface and a second side surface, a consumable component disposed in the plasma processing module, and a vacuum transport module having a third side surface, the vacuum transport module being connected to the plasma processing module to be able to transport a substrate between the vacuum transport module and the plasma processing module via a first opening of the first side surface and a third opening of the third side surface;
a portable type component storage unit, the portable type component storage unit including a housing, the housing being able to store the consumable component, and the housing having a fourth side surface and at least one lid attached to close a fourth opening of the fourth side surface; and
a mobile type replacement apparatus having a fifth side surface and a sixth side surface, the mobile type replacement apparatus being configured to be able to be connected to the plasma processing module to transport the consumable component between the mobile type replacement apparatus and the plasma processing module via a second opening of the second side surface and a fifth opening of the fifth side surface, and the mobile type replacement apparatus including a load port extending outward from the sixth side surface and configured to be able to place the portable type component storage unit, and the load port being configured to remove the at least one lid and to be able to transport the consumable component via the fourth opening of the fourth side surface and a sixth opening of the sixth side surface when the portable type component storage unit is placed on the load port, and a component replacement robot configured to transport the consumable component between the portable type component storage unit and the plasma processing module via the fourth opening, the sixth opening, the second opening, and the fifth opening when the mobile type replacement apparatus is connected to the plasma processing module and when the portable type component storage unit is placed on the load port.

In one exemplary embodiment, the plasma processing module includes a plasma processing chamber, and a substrate support disposed in the plasma processing chamber and having a substrate support surface and a ring support surface, and the consumable component is an annular member disposed on the ring support surface to surround the substrate on the substrate support surface.

In one exemplary embodiment, the plasma processing module includes a plasma processing chamber, and a substrate support disposed in the plasma processing chamber, and the consumable component is an upper electrode plate disposed above the substrate support.

In one exemplary embodiment, the plasma processing module includes a first chamber, and the consumable component is a second chamber disposed in the first chamber.

In one exemplary embodiment, the portable type component storage unit is configured to be transported by a ceiling traveling type shuttle.

In one exemplary embodiment, the housing of the portable type component storage unit is configured to store a plurality of the consumable components.

In one exemplary embodiment, the mobile type replacement apparatus further includes a falling prevention mechanism.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### First Embodiment

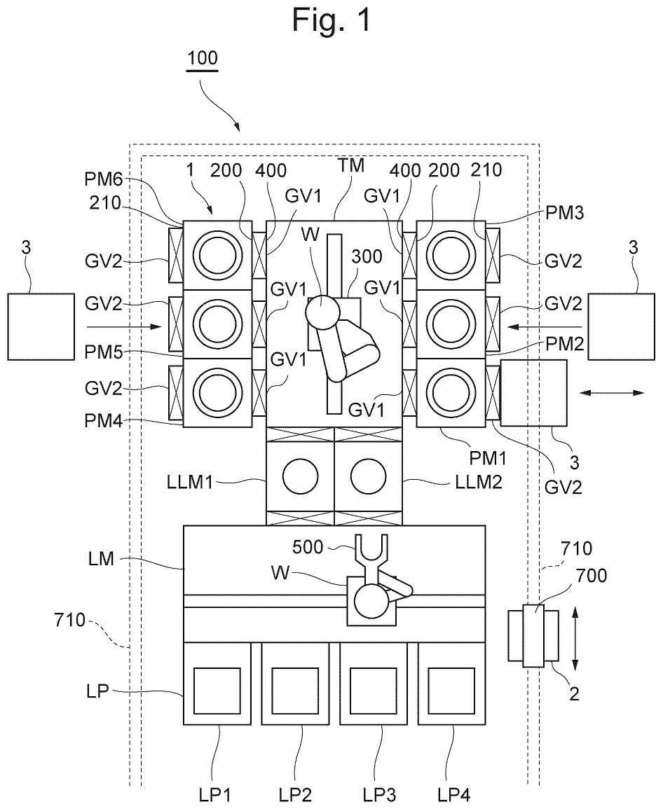

FIG. 1 is a diagram illustrating a configuration example of a component replacement system. In an embodiment, a component replacement system 100 includes a substrate processing apparatus 1, a portable type component storage unit 2, and a mobile type replacement apparatus 3.

### Example of Substrate Processing Apparatus

In an embodiment, the substrate processing apparatus 1 may have a plurality of substrate processing modules PM1 to PM6 (hereinafter, also collectively referred to as a “substrate processing module PM”), a vacuum transport module TM, load lock modules LLM1 and LLM2 (hereinafter, also collectively referred to as a “load lock module LLM”), a loader module LM, and load ports LP1 to LP4 (hereinafter, also collectively referred to as a “load port LP”). The substrate processing apparatus 1 may be able to be installed in a clean room. The substrate processing apparatus 1 is an example of the plasma processing apparatus.

In an embodiment, the substrate processing module PM may execute, in an inside thereof, processing such as etching processing, trimming processing, film forming processing, annealing processing, doping processing, lithography processing, cleaning processing, or ashing processing on a substrate W. A part or all of the substrate processing module PM may be a plasma processing module that performs plasma processing on the substrate W. At least one of the substrate processing modules PM1 to PM6 may be an apparatus that forms a capacitively coupled plasma (CCP), an inductively coupled plasma (ICP), an electron-cyclotron-resonance plasma (ECR), a helicon wave plasma (HWP), or a surface wave plasma (SWP) to perform the plasma processing. Each substrate processing module PM may be connected to the vacuum transport module TM via a gate valve GV1. The substrate processing module PM may have a first side surface 200 on a vacuum transport module TM side and a second side surface 210 on a side to which the mobile type replacement apparatus 3, which will be described later, is connected.

In an embodiment, the vacuum transport module TM may be able to make an internal pressure of the vacuum transport module TM a vacuum. In an embodiment, the vacuum transport module TM may have a transport apparatus 300 that transports the substrate W, and transport the substrate W between the substrate processing modules PM or between the substrate processing module PM and the load lock module LLM. The substrate processing module PM and the load lock module LLM may be disposed adjacent to the vacuum transport module TM. The vacuum transport module TM and the load lock module LLM may be spatially isolated or connected by an openable and closable gate valve. The vacuum transport module TM may have a third side surface 400 on a substrate processing module PM side. The vacuum transport module TM may be able to transport the substrate W between the substrate processing modules PM via a first opening portion of the first side surface 200 and a third opening portion of the third side surface 400, which are opened by the gate valve GV1.

In an embodiment, the load lock modules LLM1 and LLM2 may be provided between the vacuum transport module TM and the loader module LM. In an embodiment, the load lock module LLM may be able to switch an internal pressure of the load lock module LLM to atmospheric pressure or vacuum. The “atmospheric pressure” may be an external pressure of each module included in the substrate processing apparatus 1. In addition, the “vacuum” is a pressure lower than the atmospheric pressure, and may be, for example, a medium vacuum of 0.1 Pa to 100 Pa. In an embodiment, the load lock module LLM is able to transport the substrate W from the loader module LM having the atmospheric pressure to the vacuum transport module TM having the vacuum, and transport the substrate W from the vacuum transport module TM having vacuum to the loader module LM having the atmospheric pressure.

In an embodiment, the loader module LM may have a transport apparatus 500 that transports the substrate W, and the substrate W may be transported between the load lock module LLM and the load port LP. In an embodiment, for example, a front opening unified pod (FOUP) or an empty FOUP in which 25 substrates W are able to be accommodated may be placed inside the load port LP. In an embodiment, the loader module LM may be able to take out the substrate W from the FOUP in the load port LP and transport the substrate W to the load lock module LLM. In addition, the loader module LM may be able to take out the substrate W from the load lock module LLM and transport the substrate W to the FOUP in the load port LP.

### Example of Substrate Processing Module

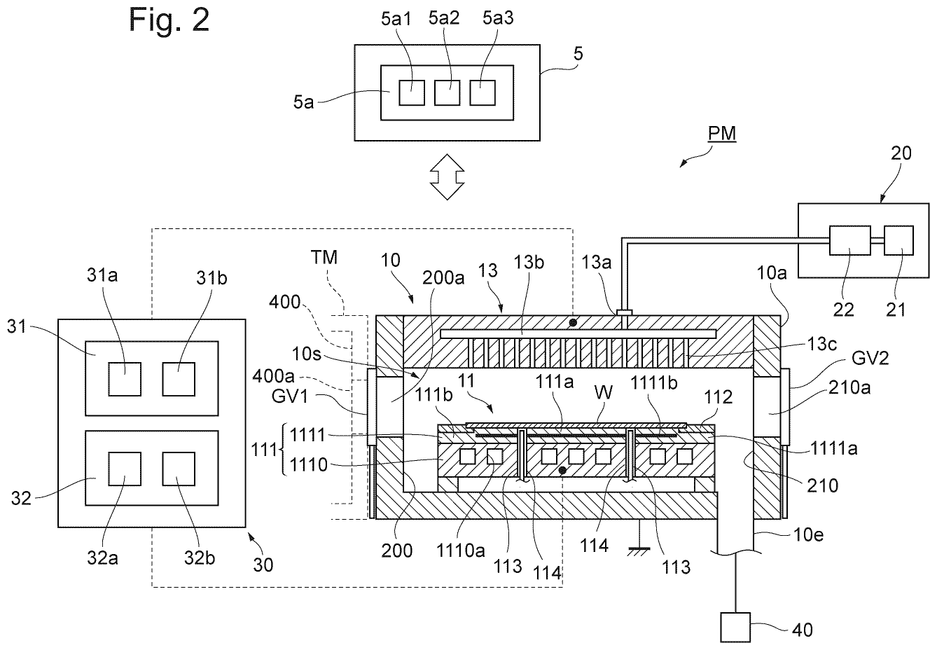

The substrate processing module PM may be a capacitively coupled plasma processing module. FIG. 2 is a diagram illustrating a configuration example of the capacitively coupled substrate processing module PM.

In an embodiment, the substrate processing module PM includes a controller 5g, a plasma processing chamber 10, a gas supply 20, a power supply 30, and an exhaust system 40. In addition, the substrate processing module PM includes a substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 has at least one gas supply port for supplying at least one processing gas to the plasma processing space 10s and at least one gas exhaust port for exhausting the gas from the plasma processing space. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting the substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. In addition, at least one RF/DC electrode coupled to a radio frequency (RF) power supply 31 and/or a direct current (DC) power supply 32, which will be described later, may be disposed in the ceramic member 1111a. In this case, at least one RF/DC electrode functions as the lower electrode. In a case where a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of the lower electrodes. Further, the electrostatic electrode 1111b may function as the lower electrode. Therefore, the substrate support 11 includes at least one lower electrode.

The ring assembly 112 includes one or a plurality of annular members. In an embodiment, one or a plurality of annular members includes one or a plurality of edge rings and at least one cover ring. The edge ring is formed from a conductive material or an insulating material, and the cover ring is formed from an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of the heaters is disposed in the ceramic member 1111a of the electrostatic chuck 1111. Further, the substrate support 11 may include a heat transfer gas supply configured to supply a heat transfer gas to a gap between a back surface of the substrate W and the center region 111a.

In an embodiment, a lifter (lift pin) 113 may be disposed on the substrate support 11. The lifter 113 is disposed in a plurality of through-holes 114 that penetrate the substrate support 11 in an up-down direction, and may be moved in the up-down direction in the through-holes 114 by a drive apparatus. In an embodiment, the substrate W may be carried in and out of the chamber 10 by the transport apparatus 300 of the vacuum transport module TM. The lifter 113 may support, and lift and lower the substrate W on the substrate support 11, exchange the substrate W with the transport apparatus 300, and place the substrate W on the substrate support 11. The lifter 113 may be able to exchange the consumable components with a component replacement robot described later.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode (upper electrode plate). In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Furthermore, the gas supply 20 may include one or more flow rate modulation devices that modulate or pulse the flow rate of at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Therefore, the RF power supply 31 may function as at least a part of a plasma generator configured to form the plasma from one or more processing gases in the plasma processing chamber 10. Further, by supplying the bias RF signal to at least one lower electrode, a bias potential is generated in the substrate W, and an ion component in the formed plasma is able to be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in the range of 10 MHz to 150 MHz. In an embodiment, the first RF generator 31a may be configured to generate a plurality of the source RF signals having different frequencies. The generated one or a plurality of source RF signals are supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has the frequency in a range of 100 kHz to 60 MHz. In an embodiment, the second RF generator 31b may be configured to generate a plurality of the bias RF signals having different frequencies. The generated one or the plurality of bias RF signals is supplied to at least one lower electrode. In addition, in various embodiments, at least one of the source RF signal and the bias RF signal may be pulsed.

In addition, the power supply 30 may include a DC power supply 32 coupled to the plasma processing chamber 10. The DC power supply 32 includes a first DC generator 32a and a second DC generator 32b. In an embodiment, the first DC generator 32a is connected to at least one lower electrode, and is configured to generate a first DC signal. The generated first bias DC signal is applied to at least one lower electrode. In an embodiment, the second DC generator 32b is connected to at least one upper electrode and is configured to generate a second DC signal. The generated second DC signal is applied to at least one upper electrode.

In various embodiments, at least one of the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of voltage pulses of the positive polarity and one or a plurality of voltage pulses of the negative polarity in one cycle. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

In an embodiment, the side wall 10a of the plasma processing chamber 10 may have a first side surface 200 on the vacuum transport module TM side and a second side surface 210 facing the first side surface 200. A first opening portion 200a may be disposed on the first side surface 200. The first opening portion 200a may be openable and closable by the gate valve GV1. The substrate processing module PM may be connected to the vacuum transport module TM to transport the substrate W via the first opening portion 200a and the opening portion 400a of the third side surface 400 of the vacuum transport module TM.

In an embodiment, a second opening portion 210a may be disposed on the second side surface 210. The second opening portion 210a may have a size through which a consumable component of the substrate processing module PM is able to pass. The second opening portion 210a may be openable and closable by the gate valve GV2. The mobile type replacement apparatus 3, which will be described later, may be connectable to the second side surface 210.

The controller 5 processes a computer-executable command for causing the substrate processing module PM to execute various steps described in the present disclosure. The controller 5 may be configured to control each element of the substrate processing module PM to execute various steps described here. In an embodiment, a part or all of the controller 5 may be included in the substrate processing module PM. The controller 5 may include a processor 5a1, a storage 5a2, and a communication interface 5a3. The controller 5 is realized by, for example, a computer 5a. The processor 5a1 may be configured to read out a program from the storage 5a2, and perform various control operations by executing the read out program. This program may be stored in the storage 5a2 in advance, or may be acquired via a medium when necessary. The acquired program is stored in the storage 5a2, and is read out from the storage 5a2 and executed by the processor 5a1. The medium may be various storage media readable by the computer 5a or may be a communication line connected to the communication interface 5a3. The processor 5a1 may be a central processing unit (CPU). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. The storage 5a2 may include a random access memory (RAM), a read only memory (ROM), a hard disk drive (HDD), a solid state drive (SSD), or a combination thereof. The communication interface 5a3 may communicate with the substrate processing module PM via a communication line such as a local area network (LAN).

### Example of Portable Type Component Storage Unit

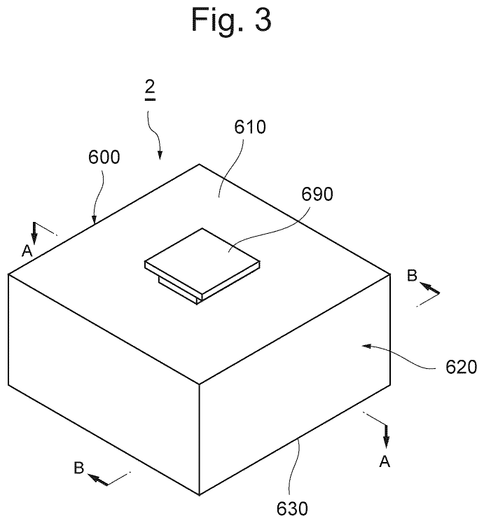

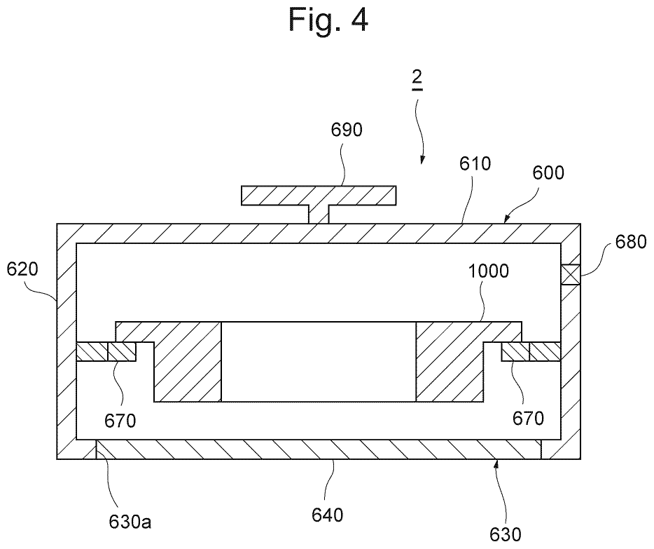

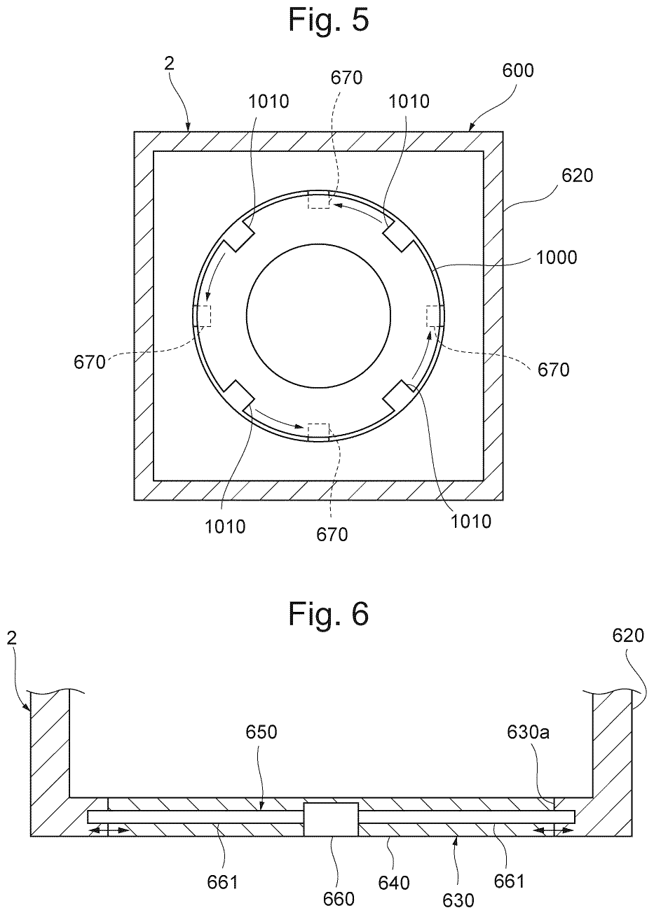

FIG. 3 is a diagram illustrating a configuration example of the portable type component storage unit 2. FIG. 4 is a diagram illustrating an example of an internal configuration of the portable type component storage unit 2 with a cross section taken along line A-A of FIG. 3. FIG. 5 is a diagram illustrating an example of the internal configuration of the portable type component storage unit 2. FIG. 5 is a diagram illustrating a cross section taken along line B-B of FIG. 3.

In an embodiment, the portable type component storage unit 2 is a container that stores and transports a consumable component 1000 used in the substrate processing module PM. In an embodiment, the portable type component storage unit 2 may include a housing 600 in which the consumable component 1000 is able to be stored. The housing 600 may have an external shape of a rectangular parallelepiped shape. In an embodiment, the housing 600 may include an upper surface 610, a side surface 620, and a bottom surface 630. The housing 600 may be configured to maintain the internal space in a vacuum or a dry atmosphere. As illustrated in FIG. 4, a bottom surface opening 630a may be disposed in the bottom surface 630. In an embodiment, the bottom surface 630 may include a bottom surface lid 640 attached to close the bottom surface opening 630a.

As illustrated in FIG. 6, the portable type component storage unit 2 may include a lock mechanism 650. The lock mechanism 650 may be configured to lock the bottom surface lid 640 to the bottom surface 630 and release the lock state. In an embodiment, the lock mechanism 650 may include a rotation portion 660 provided on the bottom surface lid 640 and a forward and backward movement portion 661 that moves forward and backward into the bottom surface 630 (housing 600) outside the bottom surface lid 640 by the rotation of the rotation portion 660. The bottom surface lid 640 may be locked to the bottom surface 630 by allowing the forward and backward movement portion 661 to enter the bottom surface 630. The lock state of the bottom surface lid 640 with respect to the bottom surface 630 may be released by the forward and backward movement portion 661 being disengaged from the bottom surface 630.

As illustrated in FIGS. 4 and 5, the portable type component storage unit 2 may include a plurality of supports 670 that support or hold the consumable component 1000 in the housing 600. Each support 670 may protrude inward from the side surface 620 of the housing 600. The support 670 may be configured to support an outer peripheral portion of the consumable component 1000. As illustrated in FIG. 5, the consumable component 1000 may have an annular shape or a circular shape, and may include a notch 1010 corresponding to the support 670 at the outer peripheral portion thereof. The positions of the notch 1010 and the support 670 may be aligned by rotating the consumable component 1000, and the consumable component 1000 may be lowered under the support 670.

The portable type component storage unit 2 may include a drying agent in the internal space. As illustrated in FIG. 4, the housing 600 of the portable type component storage unit 2 may include an exhaust port 680 for making the internal space the vacuum. A check valve that prevents the external atmosphere from entering the internal space may be disposed at the exhaust port 680.

As illustrated in FIG. 3, the portable type component storage unit 2 may include a handle 690 gripped by a ceiling traveling type shuttle on the upper surface 610. As illustrated in FIG. 1, the portable type component storage unit 2 may be configured to be transported by a ceiling traveling type shuttle 700.

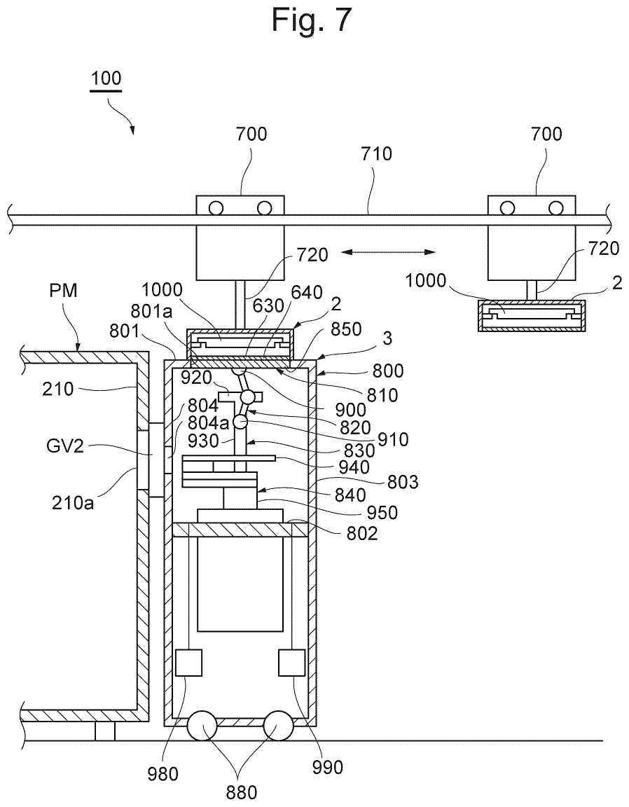

As illustrated in FIG. 1, the ceiling traveling type shuttle 700 may be able to move on a rail 710 extended on a ceiling in the clean room. The rail 710 may be extended to pass around the substrate processing module PM of the substrate processing apparatus 1 in plan view. The rail 710 may be extended to pass over the mobile type replacement apparatus 3 connected to the substrate processing module PM in plan view. As illustrated in FIG. 7, the ceiling traveling type shuttle 700 may include a lifting and lowering portion 720 that grips the portable type component storage unit 2 and moves the portable type component storage unit 2 up and down. The ceiling traveling type shuttle 700 may be able to connect the portable type component storage unit 2 to the mobile type replacement apparatus 3.

### Example of Mobile Type Replacement Apparatus

In an embodiment, the mobile type replacement apparatus 3 is an apparatus that delivers the consumable component between the portable type component storage unit 2 and the substrate processing module PM. As illustrated in FIG. 7, the mobile type replacement apparatus 3 has wheels 880 and may be configured to be self-propelled. In an embodiment, the mobile type replacement apparatus 3 may include a housing 800, a lock release mechanism 810, a lid removal mechanism 820, a lifting and lowering mechanism 830, and a component replacement robot 840.

The housing 800 may include an upper surface 801, a bottom surface 802, and a side surface 803. The housing 800 may be configured to maintain the internal space in a vacuum or a dry atmosphere. The side surface 803 may include a fourth side surface 804. A fourth opening portion 804a may be disposed on the fourth side surface 804. The fourth opening portion 804a may have a size through which the consumable component is able to pass. The fourth opening portion 804a may be openable and closable by the gate valve GV2. When the mobile type replacement apparatus 3 is connected to the substrate processing module PM, the consumable component may be able to be transported between the substrate processing module PM and the mobile type replacement apparatus 3 via the second opening portion 210a and the fourth opening portion 804a.

An upper surface opening 801a may be disposed on the upper surface 801. The upper surface 801 may include an upper surface lid 850 attached to close the upper surface opening 801a. The upper surface lid 850 may be configured to engage with the bottom surface lid 640 of the portable type component storage unit 2 when the portable type component storage unit 2 is connected to the mobile type replacement apparatus 3.

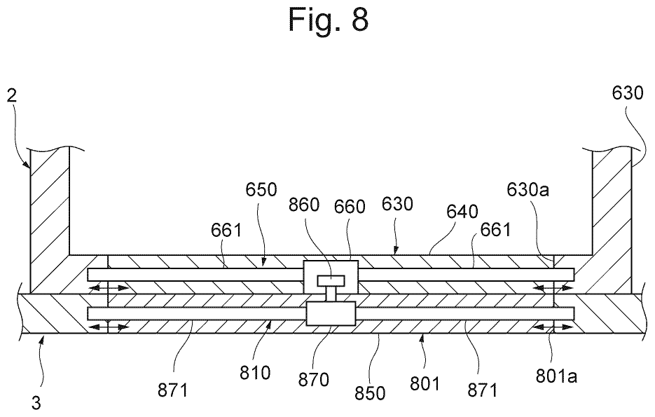

As illustrated in FIG. 8, the upper surface lid 850 includes an engaging portion 860 that protrudes upward, and the engaging portion 860 may be engaged with the rotation portion 660 as the engaged portion of the bottom surface lid 640.

The lock release mechanism 810 may be configured to release the lock states of the upper surface lid 850 and the bottom surface lid 640 when the portable type component storage unit 2 is connected to the mobile type replacement apparatus 3. The lock release mechanism 810 may include the engaging portion 860, a rotation motor 870 that rotates the engaging portion 860, and a forward and backward movement portion 871 that moves forward and backward into the upper surface 801 (housing 800) outside the upper surface lid 850 by the rotation of the rotation motor 870. First, the upper surface lid 850 may be locked to the upper surface 801 by the forward and backward movement portion 871 entering the upper surface 801 by the rotation motor 870. That is, the lock release mechanism 810 may include a function of locking the upper surface lid 850 to the upper surface 801. Next, the lock state of the upper surface lid 850 with respect to the upper surface 801 may be released by the forward and backward movement portion 871 being disengaged from the upper surface 801 by the rotation motor 870. In this case, by rotating the engaging portion 860 by the rotation motor 870, the rotation portion 660 of the bottom surface lid 640 engaged with the engaging portion 860 is rotated, and thus the forward and backward movement portion 661 may be disengaged from the bottom surface 630, whereby the lock state of the bottom surface lid 640 with respect to the bottom surface 630 may be released.

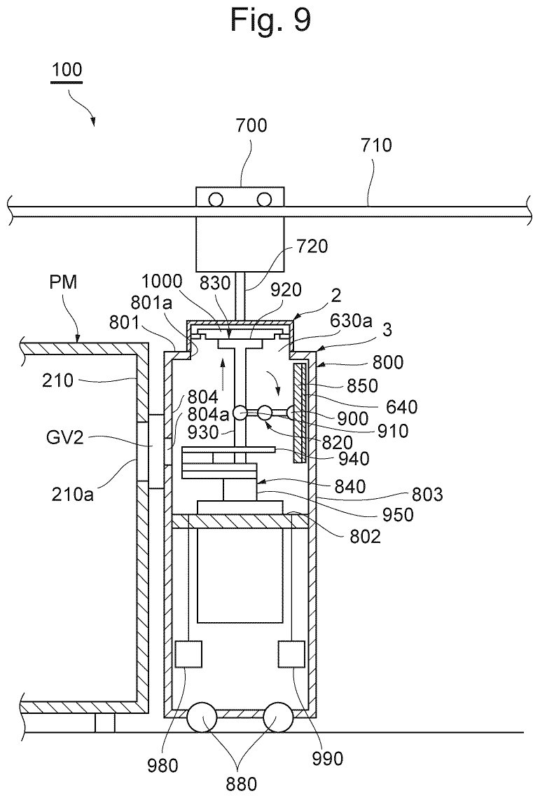

As illustrated in FIG. 7, the lid removal mechanism 820 may be configured to remove the upper surface lid 850 and the bottom surface lid 640 together when the portable type component storage unit 2 is connected to the mobile type replacement apparatus 3 and when the lock states of the upper surface lid 850 and the bottom surface lid 640 are released. The lid removal mechanism 820 may include a holding portion 900 that holds a lower surface of the upper surface lid 850 and a movement portion 910 that moves the holding portion 900. The holding portion 900 may be fixed to the upper surface lid 850 or may be attachable and detachable to the upper surface lid 850. The holding portion 900 may hold the lower surface of the upper surface lid 850 by suction. As illustrated in FIG. 9, the movement portion 910 may have a link mechanism and may rotate and swing the holding portion 900 to remove the upper surface lid 850 and the bottom surface lid 640 from the bottom surface 630 and the upper surface 801 and to retract the upper surface lid 850 and the bottom surface lid 640 from directly below the bottom surface 630 and the upper surface 801. The movement portion 910 may be supported by the housing 800.

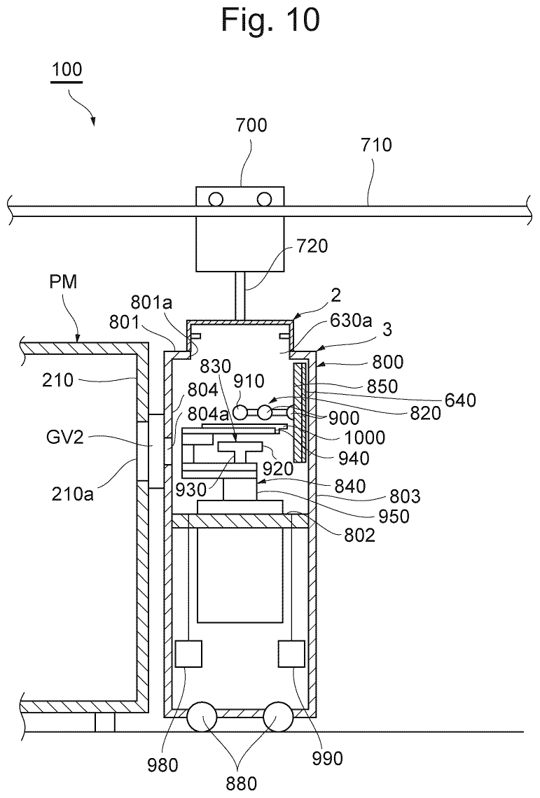

The lifting and lowering mechanism 830 may be configured to move the consumable component 1000 in the vertical direction between a first position in the portable type component storage unit 2 and a second position in the mobile type replacement apparatus 3 via the bottom surface opening 630a and the upper surface opening 801a when the portable type component storage unit 2 is connected to the mobile type replacement apparatus 3 and when the upper surface lid 850 and the bottom surface lid 640 are removed. The lifting and lowering mechanism 830 may include a holding portion 920 that holds the consumable component 1000 and a driving portion 930 that rotates and moves the holding portion 920 up and down. The holding portion 920 may hold the lower surface of the consumable component 1000 by suction. The driving portion 930 may rotate the holding portion 920 that holds the consumable component 1000 in the portable type component storage unit 2, align the notch 1010 of the consumable component 1000 with the position of the support 670, and lower the holding portion 920 in that state to take out the consumable component 1000 from the portable type component storage unit 2. In addition, as illustrated in FIG. 10, the driving portion 930 may lower the holding portion 920 that holds the consumable component 1000 and deliver the consumable component 1000 to the component replacement robot 840 in the mobile type replacement apparatus 3.

The component replacement robot 840 may be configured to transport the consumable component 1000 between the second position in the mobile type replacement apparatus 3 and the substrate processing module PM via the fourth opening portion 804a of the fourth side surface 804 and the second opening portion 210a of the second side surface 210 when the mobile type replacement apparatus 3 is connected to the substrate processing module PM. The component replacement robot 840 may include a holding arm 940 that holds the consumable component 1000, and a driving mechanism 950 that moves the holding arm 940 forward and backward, up and down, and left and right. The holding arm 940 may hold the consumable component 1000 by supporting the consumable component 1000 from below. The holding arm 940 may have a substantially U-shape. The component replacement robot 840 may enter the substrate processing module PM, attach the consumable component 1000 to a predetermined installation position, and deliver the consumable component 1000 to an attachment apparatus that attaches the consumable component 1000 to a predetermined installation position.

In an embodiment, the mobile type replacement apparatus 3 may include an exhaust apparatus 980 that exhausts the atmosphere of the internal space of the housing 800 to make the internal space of the housing 800 a vacuum, and a gas supply apparatus 990 that supplies a dry gas to the internal space of the housing 800 to make the internal space of the housing 800 a dry atmosphere.

### Example of Replacement Processing of Consumable Component

Next, an example of replacement processing of the consumable component 1000 using the component replacement system 100 will be described. The consumable component 1000 may be an annular member (edge ring, cover ring) of the ring assembly 112 disposed in the substrate processing module PM or an upper electrode plate of the shower head 13.

As illustrated in FIG. 1, the mobile type replacement apparatus 3 is connected to the substrate processing module PM including the consumable component 1000. Next, as illustrated in FIG. 7, the empty portable type component storage unit 2 is moved onto the mobile type replacement apparatus 3 by the ceiling traveling type shuttle 700, and is connected to the upper surface lid 850 of the mobile type replacement apparatus 3. The lock state of the upper surface lid 850 and the bottom surface lid 640 is released by the lock release mechanism 810. The upper surface lid 850 and the bottom surface lid 640 are removed together by the lid removal mechanism 820. In this way, the upper surface opening 801a of the upper surface 801 of the mobile type replacement apparatus 3 and the bottom surface opening 630a of the bottom surface 630 of the portable type component storage unit 2 are opened. In this case, the inside of the housing 800 of the mobile type replacement apparatus 3 is maintained in the vacuum or the dry atmosphere.

Next, the second opening portion 210a and the fourth opening portion 804a are opened by the gate valve GV2, and the consumable component 1000 disposed in the substrate processing module PM is transported into the mobile type replacement apparatus 3 by the component replacement robot 840 via the second opening portion 210a and the fourth opening portion 804a. In this case, the consumable component 1000 of the substrate processing module PM is removed by the component replacement robot 840 or the removal mechanism provided in the substrate processing module PM. The consumable component 1000 removed by the removal mechanism is delivered to the component replacement robot 840. Next, the consumable component 1000 is delivered from the component replacement robot 840 to the lifting and lowering mechanism 830, is lifted by the lifting and lowering mechanism 830, and is stored in the portable type component storage unit 2 via the upper surface opening 801a and the bottom surface opening 630a. In this case, the consumable component 1000 is supported by the support 670 of the portable type component storage unit 2.

Next, the lid removal mechanism 820 attaches the upper surface lid 850 and the bottom surface lid 640 to the upper surface 801 and the bottom surface 630 together, and the upper surface opening 801a and the bottom surface opening 630a are closed. The upper surface lid 850 is locked to the upper surface 801 and the bottom surface lid 640 is locked to the bottom surface 630 by the lock release mechanism 810 and the lock mechanism 650. Next, the portable type component storage unit 2 is transported from the mobile type replacement apparatus 3 to a predetermined component station by the ceiling traveling type shuttle 700.

Next, the portable type component storage unit 2 in which a new consumable component 1000 is accommodated is prepared. The internal space of the portable type component storage unit 2 is maintained in the vacuum or the dry atmosphere. The consumable component 1000 is supported by the support 670 in the portable type component storage unit 2.

The mobile type replacement apparatus 3 is connected to the substrate processing module PM. The portable type component storage unit 2 is moved onto the mobile type replacement apparatus 3 by the ceiling traveling type shuttle 700 and is connected to the upper surface lid 850 of the mobile type replacement apparatus 3. In this case, the bottom surface lid 640 of the portable type component storage unit 2 and the upper surface lid 850 of the mobile type replacement apparatus 3 are engaged with each other. The lock state of the upper surface lid 850 and the bottom surface lid 640 is released by the lock release mechanism 810. As illustrated in FIG. 9, the upper surface lid 850 and the bottom surface lid 640 are removed together by the lid removal mechanism 820. In this way, the upper surface opening 801a of the upper surface 801 of the mobile type replacement apparatus 3 and the bottom surface opening 630a of the bottom surface 630 of the portable type component storage unit 2 are opened. In this case, the inside of the housing 800 of the mobile type replacement apparatus 3 is maintained in the vacuum or the dry atmosphere.

Next, as illustrated in FIG. 10, the consumable component 1000 of the portable type component storage unit 2 is lowered by the lifting and lowering mechanism 830 via the upper surface opening 801a and the bottom surface opening 630a, and is delivered to the component replacement robot 840. In this case, the lifting and lowering mechanism 830 holds and rotates the consumable component 1000 of the portable type component storage unit 2, and aligns the notch 1010 of the consumable component 1000 with the position of the support 670. Then, the lifting and lowering mechanism 830 lowers the consumable component 1000 to take out the consumable component 1000 from the portable type component storage unit 2.

Next, the second opening portion 210a and the fourth opening portion 804a are opened by the gate valve GV2, and the consumable component 1000 is transported to the substrate processing module PM by the component replacement robot 840 via the second opening portion 210a and the fourth opening portion 804a. The consumable component 1000 is attached to the substrate processing module PM by the attachment apparatus provided in the component replacement robot 840 or the substrate processing module PM.

Next, the component replacement robot 840 retracts from the substrate processing module PM to the mobile type replacement apparatus 3, and the second opening portion 210a and the fourth opening portion 804a are closed by the gate valve GV2. In addition, the lid removal mechanism 820 attaches the upper surface lid 850 and the bottom surface lid 640 to the upper surface 801 and the bottom surface 630 together, and the upper surface opening 801a and the bottom surface opening 630a are closed. The upper surface lid 850 is locked to the upper surface 801 and the bottom surface lid 640 is locked to the bottom surface 630 by the lock release mechanism 810 and the lock mechanism 650. Next, the empty portable type component storage unit 2 is transported from the mobile type replacement apparatus 3 to a predetermined component station by the ceiling traveling type shuttle 700.

According to the present exemplary embodiment, the component replacement system 100 includes the portable type component storage unit 2 and the mobile type replacement apparatus 3. The mobile type replacement apparatus 3 includes the upper surface lid 850 configured to engage with the bottom surface lid 640 when the portable type component storage unit 2 is connected to the mobile type replacement apparatus 3, the lock release mechanism 810 configured to release the lock state of the upper surface lid 850 and the bottom surface lid 640 when the portable type component storage unit 2 is connected to the mobile type replacement apparatus 3, the lid removal mechanism 820 configured to remove the upper surface lid 850 and the bottom surface lid 640 together when the portable type component storage unit 2 is connected to the mobile type replacement apparatus 3 and when the lock state of the upper surface lid 850 and the bottom surface lid 640 is released, the lifting and lowering mechanism 830 configured to move the consumable component in the vertical direction between the first position in the portable type component storage unit 2 and the second position in the mobile type replacement apparatus 3 via the bottom surface opening 630a and the upper surface opening 801a when the portable type component storage unit 2 is connected to the mobile type replacement apparatus 3 and when the upper surface lid 850 and the bottom surface lid 640 are removed, and the component replacement robot 840 configured to transport the consumable component between the second position in the mobile type replacement apparatus 3 and the substrate processing module PM via the fourth opening portion 804a and the second opening portion 210a when the mobile type replacement apparatus 3 is connected to the substrate processing module PM. Accordingly, the consumable components of the plasma processing apparatus are able to be automatically replaced.

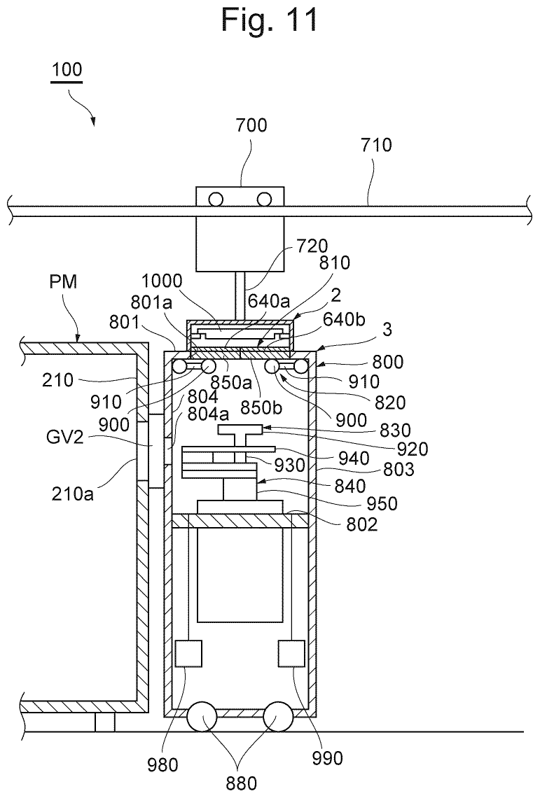

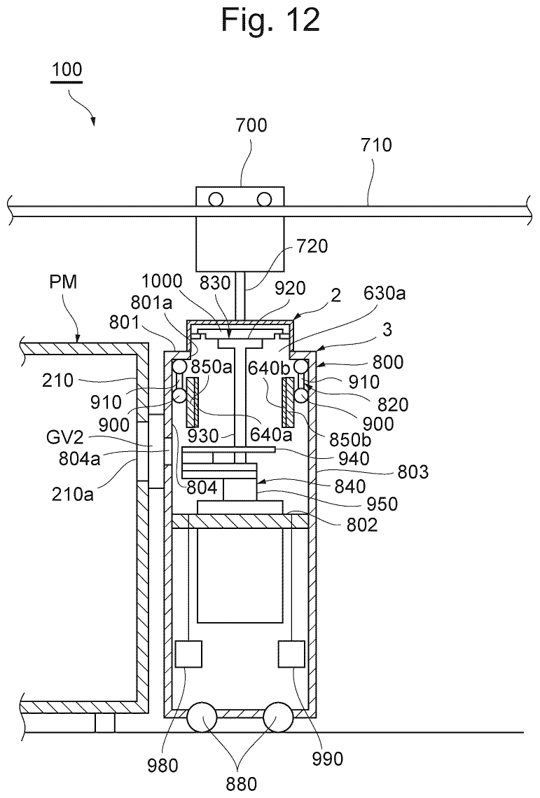

In the above-described embodiment, the portable type component storage unit 2 may include two or more N pieces of the bottom surface lids 640, the mobile type replacement apparatus 3 may include N pieces of the upper surface lids 850 corresponding to the N pieces of the bottom surface lids 640, and each upper surface lid 850 may be configured to engage with the corresponding bottom surface lid 640 when the portable type component storage unit 2 is connected to the mobile type replacement apparatus 3. In an embodiment, as illustrated in FIGS. 11 and 12, the portable type component storage unit 2 may include two bottom surface lids 640a and 640b, the mobile type replacement apparatus 3 may include two upper surface lids 850a and 850b, the upper surface lid 850a may be engaged with the bottom surface lid 640a, and the upper surface lid 850b may be engaged with the bottom surface lid 640b. The lid removal mechanism 820 may remove the bottom surface lid 640a and the upper surface lid 850a, and the upper surface lid 850b and the bottom surface lid 640b separately. According to this example, since the lid removal mechanism 820 moves the bottom surface lid and the upper surface lid which are even smaller, the space for the movement may be small, and the mobile type replacement apparatus 3 is able to be reduced in size.

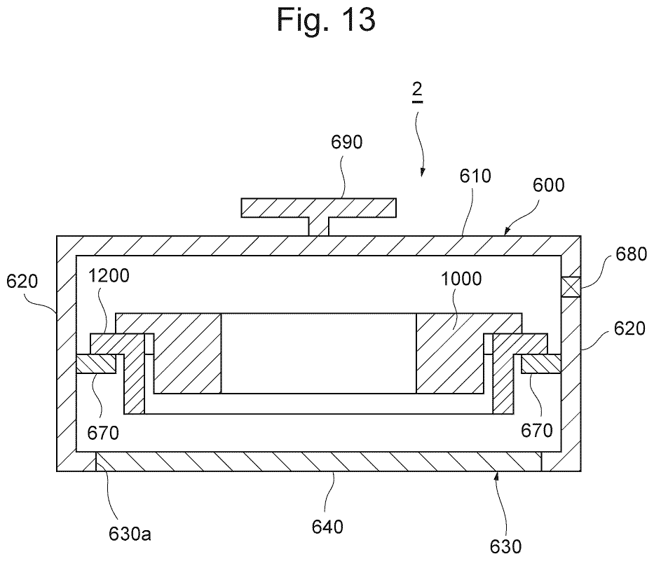

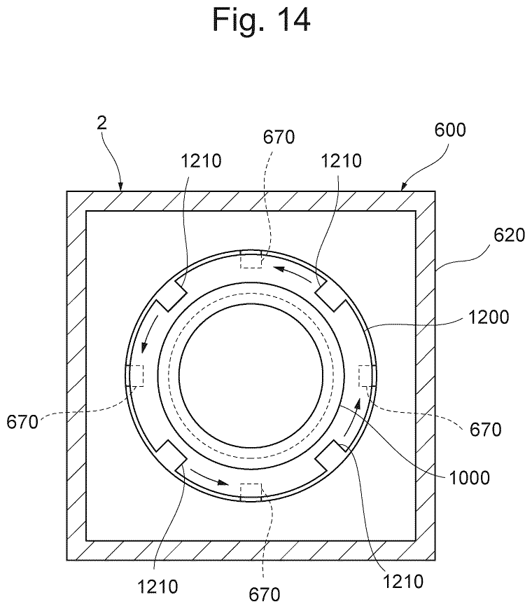

In the above-described embodiment, a jig that supports or holds the consumable component 1000 stored in the portable type component storage unit 2 may be used. In an embodiment, in a case where the consumable component 1000 includes the notch 1010 for removing from the support 670, the jig may include the notch instead of the consumable component. As illustrated in FIG. 13, in an embodiment, a jig 1200 may support the consumable component 1000 thereon. As illustrated in FIG. 14, the jig 1200 may include a notch 1210 corresponding to the support 670 of the portable type component storage unit 2 outside the portion that supports the consumable component 1000. The jig 1200 may be able to be moved below the support 670 by aligning the notch 1210 with the position of the support 670 by rotation. The jig 1200 may be held by the lifting and lowering mechanism 830 together with the consumable component 1000, and may be lowered by the lifting and lowering mechanism 830. Then, the jig 1200 may be delivered to the component replacement robot 840 together with the consumable component 1000 and may be transported to the substrate processing module PM.

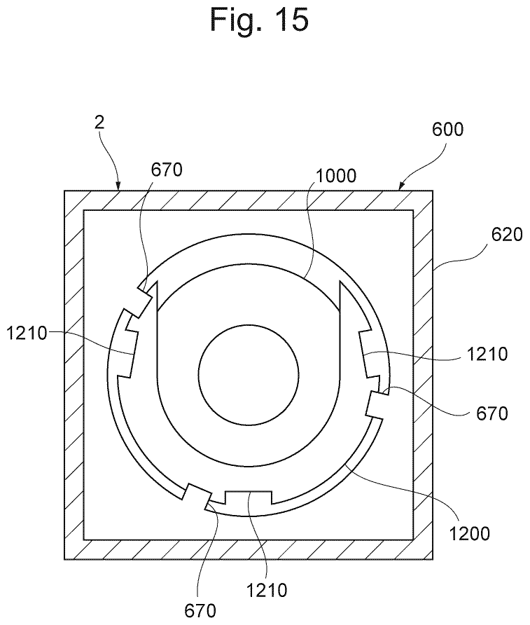

In an embodiment, the jig 1200 may have a U-shape. FIG. 15 is a diagram illustrating an example of a configuration of the jig 1200. FIG. 15 is a diagram of the jig 1200 in the portable type component storage unit 2 as viewed from below. The jig 1200 may be configured to position the lifter 113 inside the U-shape in plan view when the jig 1200 is positioned on the lifter 113 of the substrate processing module PM. In this case, in the substrate processing module PM, the lifter 113 and the jig 1200 do not interfere with each other, and the consumable component 1000 is delivered to the lifter 113. That is, the lifter 113 is lifted to lift up the consumable component 1000, and in that state, the jig 1200 and the component replacement robot 840 are able to retract from directly below the consumable component 1000.

### Second Embodiment

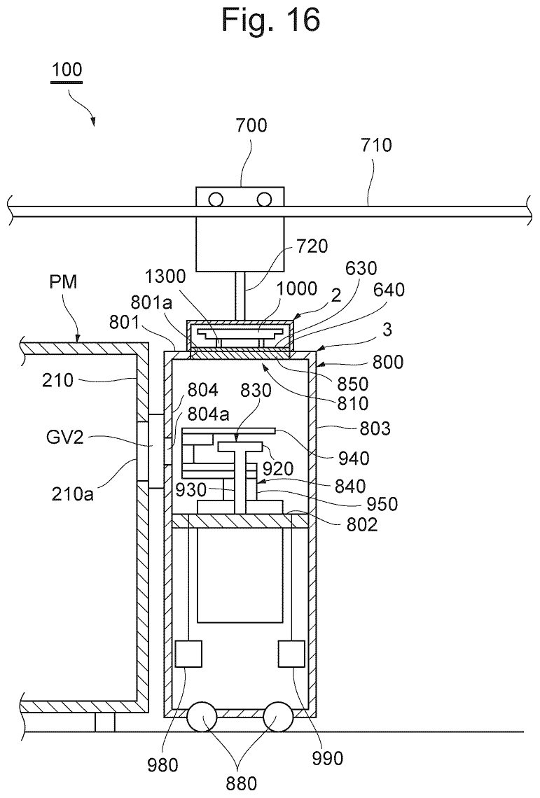

As illustrated in FIG. 16, the mobile type replacement apparatus 3 may not include the lid removal mechanism 820, and may include the housing 800, the lock release mechanism 810, the lifting and lowering mechanism 830, and the component replacement robot 840.

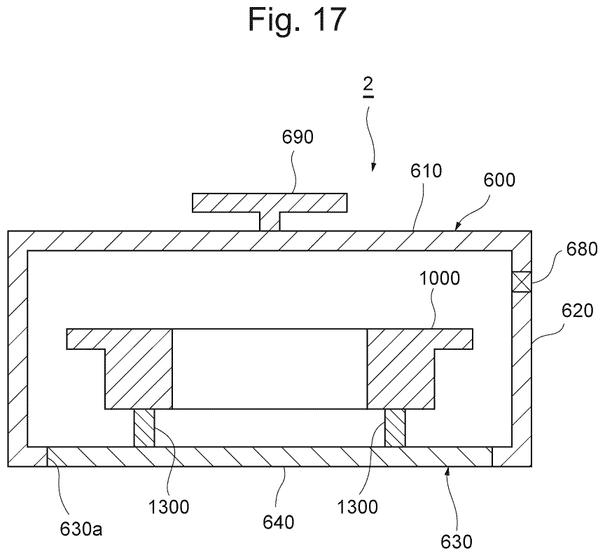

As illustrated in FIG. 17, the portable type component storage unit 2 may support the consumable component 1000 on the bottom surface lid 640. A support member 1300 may be disposed on the bottom surface lid 640, and the consumable component 1000 may be supported on the support member 1300.

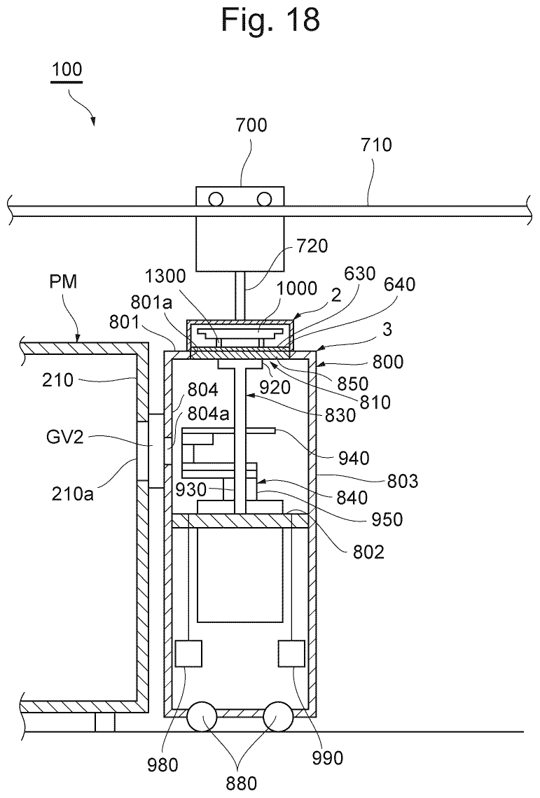

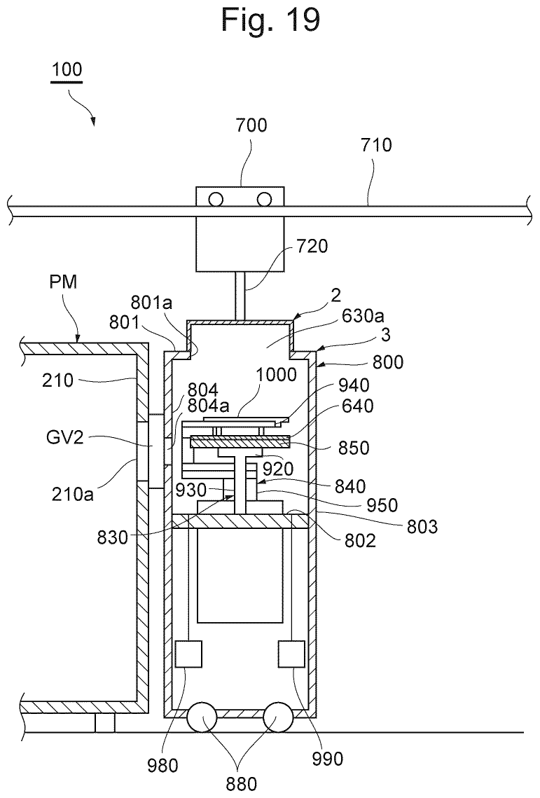

The lifting and lowering mechanism 830 may be configured to move the upper surface lid 850 and the bottom surface lid 640 together in the vertical direction, and to move the consumable component 1000 supported by the bottom surface lid 640 in the vertical direction between the first position in the portable type component storage unit 2 and the second position in the mobile type replacement apparatus 3 via the bottom surface opening 630a and the upper surface opening 801a when the portable type component storage unit 2 is connected to the mobile type replacement apparatus 3 and when the lock states of the upper surface lid 850 and the bottom surface lid 640 are released. In an embodiment, as illustrated in FIG. 16, the driving portion 930 of the lifting and lowering mechanism 830 may position the holding portion 920 in the mobile type replacement apparatus 3. As illustrated in FIG. 18, the driving portion 930 may lift the holding portion 920, and the holding portion 920 may hold the lower surface of the upper surface lid 850. As illustrated in FIG. 19, the driving portion 930 may lower the holding portion 920 holding the upper surface lid 850 together with the bottom surface lid 640 and the consumable component 1000, and deliver the consumable component 1000 to the component replacement robot 840. Other configurations including the housing 800, the lock release mechanism 810, and the component replacement robot 840 in the component replacement system 100 may be the same as those in the first embodiment.

In an example of the replacement processing of the consumable component, the portable type component storage unit 2 is moved onto the mobile type replacement apparatus 3 by the ceiling traveling type shuttle 700 and is connected to the upper surface lid 850 of the mobile type replacement apparatus 3. In this case, the upper surface lid 850 and the bottom surface lid 640 are engaged with each other. The lock state of the upper surface lid 850 and the bottom surface lid 640 is released by the lock release mechanism 810. Then, the upper surface lid 850 and the bottom surface lid 640 are lowered together by the lifting and lowering mechanism 830, and the consumable component 1000 supported by the bottom surface lid 640 in the portable type component storage unit 2 is transported into the mobile type replacement apparatus 3 and delivered to the component replacement robot 840. After that, the consumable component 1000 is transported to the substrate processing module PM by the component replacement robot 840.

### Third Embodiment

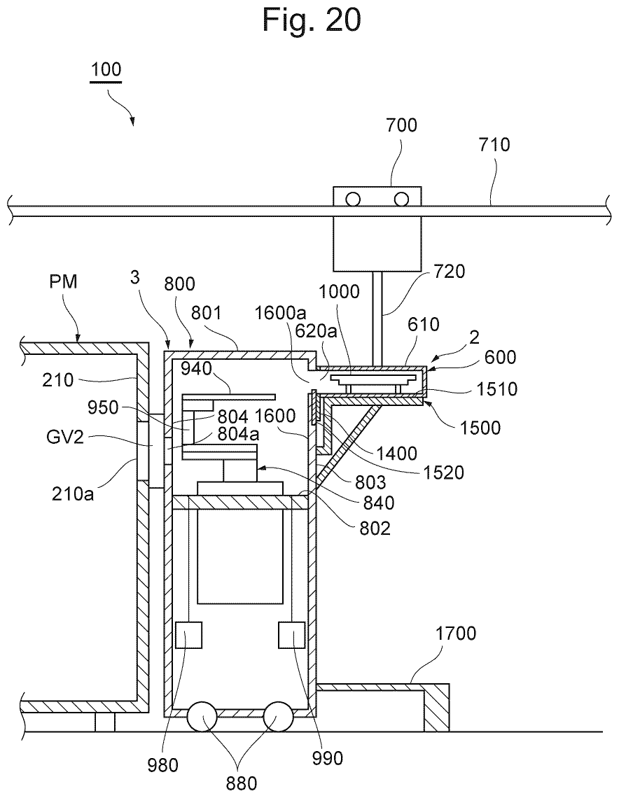

As illustrated in FIG. 20, the mobile type replacement apparatus 3 may include the housing 800, a load port 1500, and the component replacement robot 840.

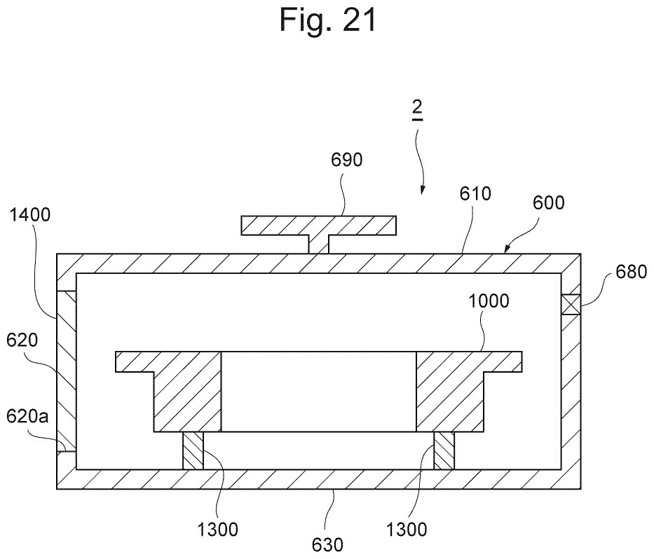

As illustrated in FIG. 21, the housing 600 of the portable type component storage unit 2 includes the side surface 620 as the fourth side surface, and a side surface opening portion 620a as the fourth opening may be disposed on the side surface 620. The side surface 620 may include a lid 1400 attached to close the side surface opening portion 620a. The portable type component storage unit 2 may include the support member 1300 that supports the consumable component 1000 on the bottom surface 630.

As illustrated in FIG. 20, the side surface 803 of the housing 800 may include a sixth side surface 1600 facing a fifth side surface 804. The fifth side surface 804 may be the fourth side surface 804 in the first embodiment. A fifth opening portion 804a may be disposed on the fifth side surface 804. A sixth opening portion 1600a may be disposed on the sixth side surface 1600. The sixth opening portion 1600a may have a size through which the consumable component 1000 is able to pass.

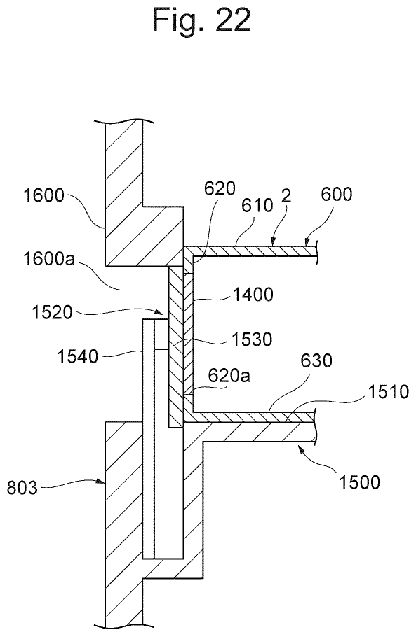

The load port 1500 may be configured to extend outward from the sixth side surface 1600 and to be able to place the portable type component storage unit 2. The load port 1500 may be configured to remove the lid 1400, and to be able to transport the consumable component 1000 via the side surface opening portion 620a of the side surface 620 and the sixth opening portion 1600a of the sixth side surface 1600 when the portable type component storage unit 2 is placed on the load port 1500. In an embodiment, as illustrated in FIG. 22, the load port 1500 may include a placing portion 1510 on which the portable type component storage unit 2 is placed, and an opening and closing mechanism 1520 that opens and closes the lid 1400.

The opening and closing mechanism 1520 may include a holding portion 1530 that holds the lid 1400 and a movement portion 1540 that moves the holding portion 1530. The holding portion 1530 may hold the side surface of the lid 1400 by suction. The movement portion 1540 may have a link mechanism and may rotate and swing the holding portion 1530 to remove the lid 1400 from the side surface 620 and retract the lid 1400 from the front of the side surface opening portion 620a and the sixth opening portion 1600a. Further, the holding portion 1530 may be a lid that opens and closes the fifth opening portion 804a.

The component replacement robot 840 illustrated in FIG. 20 may be configured to transport the consumable component 1000 between the portable type component storage unit 2 and the substrate processing module PM via the side surface opening portion 620a, the sixth opening portion 1600a, the second opening portion 210a, and the fifth opening portion 804a when the mobile type replacement apparatus 3 is connected to the substrate processing module PM and when the portable type component storage unit 2 is placed on the load port 1500.

The mobile type replacement apparatus 3 may further include a falling prevention mechanism 1700 for preventing the mobile type replacement apparatus 3 from falling. Other configurations of the component replacement system 100 may be the same as those of the first or second embodiment.

In an example of the replacement processing of the consumable component, the portable type component storage unit 2 is moved onto the mobile type replacement apparatus 3 by the ceiling traveling type shuttle 700 and is placed on the load port 1500 of the mobile type replacement apparatus 3. The lid 1400 is removed by the load port 1500, and the side surface opening portion 620a and the sixth opening portion 1600a are opened. Next, the component replacement robot 840 transports the consumable component 1000 of the portable type component storage unit 2 to the substrate processing module PM via the side surface opening portion 620a, the sixth opening portion 1600a, the second opening portion 210a, and the fifth opening portion 804a.

In the first to third embodiments, the consumable component 1000 is an annular member disposed on the ring support surface to surround the substrate W on the substrate support surface of the substrate support 11 or an upper electrode plate disposed above the substrate support 11, but may be other components. In addition, the substrate processing module PM may include a first chamber, and the consumable component 1000 may be a second chamber disposed in the first chamber. The second chamber may form a plasma processing space on the substrate support in the first chamber. In an embodiment, the second chamber may include an upper plate that extends in the horizontal direction above the substrate support, an annular bottom plate that extends outward from a side wall of the substrate support, and an inner side wall that extends in the vertical direction to connect an outer periphery of the upper plate and an outer periphery of the annular bottom plate, and the plasma processing space may be defined by the substrate support, the upper plate, the annular bottom plate, and the inner side wall. The housing of the portable type component storage unit 2 may be able to store a plurality of the consumable components 1000.

The embodiments of the present disclosure further include the following aspects.

### (Addendum 1)

A component replacement system including:
a plasma processing apparatus, the plasma processing apparatus including
   a plasma processing module having a first side surface and a second side surface,
   a consumable component disposed in the plasma processing module, and
   a vacuum transport module having a third side surface, the vacuum transport module being connected to the plasma processing module to be able to transport a substrate between the vacuum transport module and the plasma processing module via a first opening of the first side surface and a third opening of the third side surface;
a portable type component storage unit, the portable type component storage unit including a housing, the housing being able to store the consumable component, the housing including at least one bottom surface lid attached to close a bottom surface opening of a bottom surface, and the at least one bottom surface lid being locked to the bottom surface; and
a mobile type replacement apparatus having a fourth side surface and an upper surface, the mobile type replacement apparatus including
   at least one upper surface lid attached to close an upper surface opening of the upper surface, the at least one upper surface lid being locked to the upper surface, and the at least one upper surface lid being configured to engage with the at least one bottom surface lid when the portable type component storage unit is connected to the mobile type replacement apparatus,
   a lock release mechanism configured to release a lock state of the at least one upper surface lid and the at least one bottom surface lid when the portable type component storage unit is connected to the mobile type replacement apparatus,
   a lid removal mechanism configured to remove the at least one upper surface lid and the at least one bottom surface lid together when the portable type component storage unit is connected to the mobile type replacement apparatus and when the lock state of the at least one upper surface lid and the at least one bottom surface lid is released,
   a lifting and lowering mechanism configured to move the consumable component in a vertical direction between a first position in the portable type component storage unit and a second position in the mobile type replacement apparatus via the bottom surface opening and the upper surface opening when the portable type component storage unit is connected to the mobile type replacement apparatus and when the at least one upper surface lid and the at least one bottom surface lid are removed, and
   a component replacement robot configured to transport the consumable component between the second position in the mobile type replacement apparatus and the plasma processing module via a fourth opening of the fourth side surface and a second opening of the second side surface when the mobile type replacement apparatus is connected to the plasma processing module.

### (Addendum 2)

The component replacement system according to Addendum 1, in which
the plasma processing module includes
   a plasma processing chamber, and
   a substrate support disposed in the plasma processing chamber and having a substrate support surface and a ring support surface, and
   the consumable component is an annular member disposed on the ring support surface to surround the substrate on the substrate support surface.

### (Addendum 3)

The component replacement system according to Addendum 1, in which
the plasma processing module includes
   a plasma processing chamber, and
   a substrate support disposed in the plasma processing chamber, and the consumable component is an upper electrode plate disposed above the substrate support.

### (Addendum 4)

The component replacement system according to Addendum 1, in which
the plasma processing module includes a first chamber, and
   the consumable component is a second chamber disposed in the first chamber.

### (Addendum 5)

The component replacement system according to any one of Addenda 1 to 4, in which
the at least one bottom surface lid includes N (N is an integer of 2 or more) bottom surface lids,
the at least one upper surface lid includes N upper surface lids each corresponding to the N bottom surface lids, and
each upper surface lid is configured to engage with a corresponding bottom surface lid when the portable type component storage unit is connected to the mobile type replacement apparatus.

### (Addendum 6)

The component replacement system according to any one of Addenda 1 to 5, in which
the portable type component storage unit is configured to be transported by a ceiling traveling type shuttle.

### (Addendum 7)

A component replacement system including:
a plasma processing apparatus, the plasma processing apparatus including
   a plasma processing module having a first side surface and a second side surface,
   a consumable component disposed in the plasma processing module, and
   a vacuum transport module having a third side surface, the vacuum transport module being connected to the plasma processing module to be able to transport a substrate between the vacuum transport module and the plasma processing module via a first opening of the first side surface and a third opening of the third side surface;
a portable type component storage unit, the portable type component storage unit including a housing, the housing being able to store the consumable component, the housing including at least one bottom surface lid attached to close a bottom surface opening of a bottom surface, and the at least one bottom surface lid being locked to the bottom surface; and
a mobile type replacement apparatus having a fourth side surface and an upper surface, the mobile type replacement apparatus including
   at least one upper surface lid attached to close an upper surface opening of the upper surface, the at least one upper surface lid being locked to the upper surface, and the at least one upper surface lid being configured to engage with the at least one bottom surface lid when the portable type component storage unit is connected to the mobile type replacement apparatus,
   a lock release mechanism configured to release a lock state of the at least one upper surface lid and the at least one bottom surface lid when the portable type component storage unit is connected to the mobile type replacement apparatus,
   a lifting and lowering mechanism configured to move the at least one upper surface lid and the at least one bottom surface lid together in a vertical direction, and to move the consumable component supported by the at least one bottom surface lid in the vertical direction between a first position in the portable type component storage unit and a second position in the mobile type replacement apparatus via the bottom surface opening and the upper surface opening, when the portable type component storage unit is connected to the mobile type replacement apparatus and when the lock state of the at least one upper surface lid and the at least one bottom surface lid is released, and
   a component replacement robot configured to transport the consumable component between the second position in the mobile type replacement apparatus and the plasma processing module via a fourth opening of the fourth side surface and a second opening of the second side surface when the mobile type replacement apparatus is connected to the plasma processing module.

### (Addendum 8)

The component replacement system according to Addendum 7, in which
the plasma processing module includes
   a plasma processing chamber, and
   a substrate support disposed in the plasma processing chamber and having a substrate support surface and a ring support surface, and
the consumable component is an annular member disposed on the ring support surface to surround the substrate on the substrate support surface.

### (Addendum 9)

The component replacement system according to Addendum 7, in which
the plasma processing module includes
   a plasma processing chamber, and
   a substrate support disposed in the plasma processing chamber, and
the consumable component is an upper electrode plate disposed above the substrate support.

### (Addendum 10)

The component replacement system according to Addendum 7, in which
the plasma processing module includes a first chamber, and
the consumable component is a second chamber disposed in the first chamber.

### (Addendum 11)

The component replacement system according to any one of Addenda 7 to 10, in which
the at least one bottom surface lid includes N (N is an integer of 2 or more) bottom surface lids,
the at least one upper surface lid includes N upper surface lids each corresponding to the N bottom surface lids, and
each upper surface lid is configured to engage with a corresponding bottom surface lid when the portable type component storage unit is connected to the mobile type replacement apparatus.

### (Addendum 12)

The component replacement system according to any one of Addenda 7 to 11, in which
the portable type component storage unit is configured to be transported by a ceiling traveling type shuttle.

### (Addendum 13)

A component replacement system including:
a plasma processing apparatus, the plasma processing apparatus including
   a plasma processing module having a first side surface and a second side surface,
   a consumable component disposed in the plasma processing module, and
   a vacuum transport module having a third side surface, the vacuum transport module being connected to the plasma processing module to be able to transport a substrate between the vacuum transport module and the plasma processing module via a first opening of the first side surface and a third opening of the third side surface;
a portable type component storage unit, the portable type component storage unit including a housing, the housing being able to store the consumable component, and the housing having a fourth side surface and at least one lid attached to close a fourth opening of the fourth side surface; and
a mobile type replacement apparatus having a fifth side surface and a sixth side surface,
the mobile type replacement apparatus being configured to be able to be connected to the plasma processing module to transport the consumable component between the mobile type replacement apparatus and the plasma processing module via a second opening of the second side surface and a fifth opening of the fifth side surface, and
the mobile type replacement apparatus including
   a load port extending outward from the sixth side surface and configured to be able to place the portable type component storage unit, and the load port being configured to remove the at least one lid and to be able to transport the consumable component via the fourth opening of the fourth side surface and a sixth opening of the sixth side surface when the portable type component storage unit is placed on the load port, and
   a component replacement robot configured to transport the consumable component between the portable type component storage unit and the plasma processing module via the fourth opening, the sixth opening, the second opening, and the fifth opening when the mobile type replacement apparatus is connected to the plasma processing module and when the portable type component storage unit is placed on the load port.

### (Addendum 14)

The component replacement system according to Addendum 13, in which
the plasma processing module includes
   a plasma processing chamber, and
   a substrate support disposed in the plasma processing chamber and having a substrate support surface and a ring support surface, and
the consumable component is an annular member disposed on the ring support surface to surround the substrate on the substrate support surface.

### (Addendum 15)

The component replacement system according to Addendum 13, in which
the plasma processing module includes
   a plasma processing chamber, and
   a substrate support disposed in the plasma processing chamber, and
the consumable component is an upper electrode plate disposed above the substrate support.

### (Addendum 16)

The component replacement system according to Addendum 13, in which
the plasma processing module includes a first chamber, and
the consumable component is a second chamber disposed in the first chamber.

### (Addendum 17)

The component replacement system according to any one of Addenda 13 to 16, in which
the portable type component storage unit is configured to be transported by a ceiling traveling type shuttle.

### (Addendum 18)

The component replacement system according to any one of Addenda 1 to 17, in which
the housing of the portable type component storage unit is able to store a plurality of the consumable components.

### (Addendum 19)

The component replacement system according to any one of Addenda 1 to 18, in which
the mobile type replacement apparatus further includes a falling prevention mechanism.

Each of the above-described embodiments is described for the purpose of explanation, and is not intended to limit the scope of the present disclosure. Each of the above-described embodiments may be modified in various ways without departing from the scope and spirit of the present disclosure. For example, some configuration elements in one embodiment are able to be added to another embodiment. In addition, some configuration elements in one embodiment are able to be replaced with some configuration elements corresponding to another embodiment.

According to one exemplary embodiment of the present disclosure, it is possible to provide a technique capable of automatically replacing a consumable component used in a plasma processing apparatus.

What is claimed is:

1. A component replacement system, comprising:
a plasma processing apparatus including:
a plasma processing module having a first side surface and a second side surface, wherein the first side surface includes a first opening and the second side surface includes a second opening;
a consumable component disposed in the plasma processing module; and
a vacuum transport module having a third side surface, wherein the vacuum transport module is connected to the plasma processing module such that a substrate is transported between the vacuum transport module and the plasma processing module via the first opening surface and a third opening;
a portable type component storage container including a housing to store the consumable component, wherein the housing includes at least one bottom surface lid attached to close a bottom surface opening of a bottom surface, and the at least one bottom surface lid is locked to the bottom surface; and
a mobile type replacement apparatus having a fourth side surface and an upper surface, the mobile type replacement apparatus including:
at least one upper surface lid attached to close an upper surface opening of the upper surface, wherein the at least one upper surface lid is locked to the upper surface, and the at least one upper surface lid engages with the at least one bottom surface lid when the portable type component storage container is connected to the mobile type replacement apparatus;
a lock release mechanism to release a lock state of the at least one upper surface lid and the at least one bottom surface lid when the portable type component storage container is connected to the mobile type replacement apparatus;
a lid removal mechanism to remove the at least one upper surface lid and the at least one bottom surface lid together when the portable type component storage container is connected to the mobile type replacement apparatus and when the lock state of the at least one upper surface lid and the at least one bottom surface lid is released;
a lifting and lowering mechanism to move the consumable component in a vertical direction between a first position in the portable type component storage container and a second position in the mobile type replacement apparatus via the bottom surface opening and the upper surface opening when the portable type component storage container is connected to the mobile type replacement apparatus and when the at least one upper surface lid and the at least one bottom surface lid are removed; and
a component replacement robot to transport the consumable component between the second position in the mobile type replacement apparatus and the plasma processing module via a fourth opening of the fourth side surface and the second opening when the mobile type replacement apparatus is connected to the plasma processing module.

2. The component replacement system according to claim 1, wherein
the plasma processing module includes
a plasma processing chamber, and
a substrate support disposed in the plasma processing chamber and having a substrate support surface and a ring support surface, and
the consumable component is an annular member disposed on the ring support surface to surround the substrate on the substrate support surface.

3. The component replacement system according to claim 1, wherein
the plasma processing module includes
a plasma processing chamber, and
a substrate support disposed in the plasma processing chamber, and
the consumable component is an upper electrode plate disposed above the substrate support.

4. The component replacement system according to claim 1, wherein
the plasma processing module includes a first chamber, and
the consumable component is a second chamber disposed in the first chamber.

5. The component replacement system according to claim 1, wherein
the at least one bottom surface lid includes N bottom surface lids,
N is an integer of 2 or more,
the at least one upper surface lid includes N upper surface lids each corresponding to the N bottom surface lids, and
each upper surface lid is to engage with a corresponding bottom surface lid when the portable type component storage container is connected to the mobile type replacement apparatus.

6. The component replacement system according to claim 1, wherein
the portable type component storage container is transported by a ceiling traveling type shuttle.

7. A component replacement system, comprising:
a plasma processing apparatus including:
a plasma processing module having a first side surface and a second side surface, wherein the first side surface includes a first opening and the second side surface includes a second opening;
a consumable component disposed in the plasma processing module; and
a vacuum transport module having a third side surface, wherein the vacuum transport module is connected to the plasma processing module such that a substrate is transported between the vacuum transport module and the plasma processing module via the first opening and a third opening of the third side surface;
a portable type component storage container including a housing to store the consumable component, wherein the housing includes at least one bottom surface lid attached to close a bottom surface opening of a bottom surface, and the at least one bottom surface lid is locked to the bottom surface; and
a mobile type replacement apparatus having a fourth side surface and an upper surface, the mobile type replacement apparatus including:
at least one upper surface lid attached to close an upper surface opening of the upper surface, wherein the at least one upper surface lid is locked to the upper surface, and the at least one upper surface lid engages with the at least one bottom surface lid when the portable type component storage container is connected to the mobile type replacement apparatus;
a lock release mechanism to release a lock state of the at least one upper surface lid and the at least one bottom surface lid when the portable type component storage container is connected to the mobile type replacement apparatus;
a lifting and lowering mechanism to move the at least one upper surface lid and the at least one bottom surface lid together in a vertical direction, and to move the consumable component supported by the at least one bottom surface lid in the vertical direction between a first position in the portable type component storage container and a second position in the mobile type replacement apparatus via the bottom surface opening and the upper surface opening, when the portable type component storage container is connected to the mobile type replacement apparatus and when the lock state of the at least one upper surface lid and the at least one bottom surface lid is released; and
a component replacement robot to transport the consumable component between the second position in the mobile type replacement apparatus and the plasma processing module via a fourth opening of the fourth side surface and the second opening when the mobile type replacement apparatus is connected to the plasma processing module.

8. The component replacement system according to claim 7, wherein
the plasma processing module includes
a plasma processing chamber, and
a substrate support disposed in the plasma processing chamber and having a substrate support surface and a ring support surface, and
the consumable component is an annular member disposed on the ring support surface to surround the substrate on the substrate support surface.

9. The component replacement system according to claim 7, wherein
the plasma processing module includes
a plasma processing chamber, and
a substrate support disposed in the plasma processing chamber, and
the consumable component is an upper electrode plate disposed above the substrate support.

10. The component replacement system according to claim 7, wherein
the plasma processing module includes a first chamber, and
the consumable component is a second chamber disposed in the first chamber.

11. The component replacement system according to claim 7, wherein
the at least one bottom surface lid includes N bottom surface lids,
N is an integer of 2 or more,
the at least one upper surface lid includes N upper surface lids each corresponding to the N bottom surface lids, and
each upper surface lid is configured to engage with a corresponding bottom surface lid when the portable type component storage container is connected to the mobile type replacement apparatus.

12. The component replacement system according to claim 7, wherein
the portable type component storage container is transported by a ceiling traveling type shuttle.

13. A component replacement system, comprising:
a plasma processing apparatus including:
a plasma processing module having a first side surface and a second side surface, wherein the first side surface includes a first opening and the second side surface includes a second opening;
a consumable component disposed in the plasma processing module; and
a vacuum transport module having a third side surface, wherein the vacuum transport module is connected to the plasma processing module such that a substrate is transported between the vacuum transport module and the plasma processing module via the first opening and a third opening of the third side surface;
a portable type component storage container including a housing to store the consumable component, wherein the housing has a fourth side surface and at least one lid attached to close a fourth opening of the fourth side surface; and
a mobile type replacement apparatus having a fifth side surface and a sixth side surface, wherein
the mobile type replacement apparatus is connected to the plasma processing module to transport the consumable component between the mobile type replacement apparatus and the plasma processing module via the second opening and a fifth opening of the fifth side surface, and
the mobile type replacement apparatus includes:
a load port which extends outward from the sixth side surface and upon which the portable type component storage container is placed, the load port to remove the at least one lid and to transport the consumable component via the fourth opening and a sixth opening of the sixth side surface when the portable type component storage container is placed on the load port, and
a component replacement robot to transport the consumable component between the portable type component storage container and the plasma processing module via the fourth opening, the sixth opening, the second opening, and the fifth opening when the mobile type replacement apparatus is connected to the plasma processing module and when the portable type component storage container is placed on the load port.

14. The component replacement system according to claim 13, wherein
the plasma processing module includes
a plasma processing chamber, and
a substrate support disposed in the plasma processing chamber and having a substrate support surface and a ring support surface, and
the consumable component is an annular member disposed on the ring support surface to surround the substrate on the substrate support surface.

15. The component replacement system according to claim 13, wherein
the plasma processing module includes
a plasma processing chamber, and
a substrate support disposed in the plasma processing chamber, and
the consumable component is an upper electrode plate disposed above the substrate support.

16. The component replacement system according to claim 13, wherein
the plasma processing module includes a first chamber, and
the consumable component is a second chamber disposed in the first chamber.

17. The component replacement system according to claim 13, wherein
the portable type component storage container is transported by a ceiling traveling type shuttle.

18. The component replacement system according to claim 13, wherein
the housing of the portable type component storage container stores a plurality of the consumable components.

19. The component replacement system according to claim 13, wherein
the mobile type replacement apparatus further includes a falling prevention mechanism.
